(19) United States
(12) Patent Application Publication
(10) Pub. No.: US 2007/0264427 A1
(43) Pub. Date: Nov. 15, 2007

(54) THIN FILM FORMATION BY ATOMIC LAYER GROWTH AND CHEMICAL VAPOR DEPOSITION

(75) Inventors: Hiroshi SHINRIKI, Tokyo (JP); Junichi ARAMI, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/613,089

(22) Filed: Dec. 19, 2006

Related U.S. Application Data
(60) Provisional application No. 60/752,728, filed on Dec. 21, 2005.

(51) Int. Cl. C23C 16/00

(52) U.S. Cl. 427/255.7

(57) ABSTRACT

A method for forming a thin film on a substrate using a showerhead includes forming an atomic layer deposition (ALD) film and a chemical vapor deposition (CVD) film continuously, or forming a thermal ALD film and a plasma ALD film continuously, by using a showerhead including an upper compartment and a lower compartment which is disposed underneath and overlapped by the upper compartment as viewed in an axial direction of the showerhead and is not gas-communicated with the upper compartment.

### CROSS REFERENCE TO RELATED APPLICATIONS

The present application claims the benefit of U.S. Provisional Application No. 60/752,728, filed Dec. 21, 2005, the disclosure of which is incorporated herein by reference in its entirety.

### BACKGROUND OF THE INVENTION

1. Field of the Invention

The present invention relates to a single-wafer type thin-film formation apparatus that forms film on processing targets, or semiconductor wafers, one by one.

2. Description of the Related Art

Among thin-film formation apparatuses used for atomic layer deposition, showerhead types can supply material onto the substrate surface at a uniform gas concentration, while laminar-flow types tend to have different gas concentrations between upper flows and lower flows. On the other hand, showerhead type apparatuses collect material gas inside the showerhead and supply it to the substrate through the dispersion plate offering a relatively small conductance, in order to supply gas uniformly onto the substrate surface. For this reason, supply of first gas is followed by exhaust of residual first gas using second gas, after which third gas is introduced. If first gas remains, however, solid matter is produced inside the showerhead in the gaseous phase due to chemical reaction. Accordingly, due caution is required to be exercised to prevent first gas from remaining inside the dispersion apparatus (shower head) when third gas is supplied. Particularly when material of low vapor pressure is used, discharging time of residual gas becomes longer and the residual gas tends to remain.

When thin film is formed by means of chemical vapor reaction involving two or more material gases, these two or more highly reactive gases are required to be supplied separately into the reaction chamber. In general, this is done using a post-mix showerhead. U.S. patent application Ser. No. 10/824,798 (which is commonly owned by the assignee of the present application, and the disclosure of which is incorporated herein by reference in its entirety) discloses a structure in which a post-mix showerhead is used along with exhaust valves directly connected to respective gas dispersion chambers to allow reaction gases to be discharged from the exhaust valves without passing through the dispersion plate at the shower plate, as well as an atomic layer deposition process that uses the aforementioned structure.

### SUMMARY OF THE INVENTION

Although the purpose of the atomic layer deposition process is to supply materials alternately, film will not grow further once saturation is achieved at the atomic layer level, and therefore the surface density at the gas outlet of the dispersion plate need not be constant even when reaction gas is not supplied uniformly onto the substrate surface. If the same apparatus is used to perform the atomic layer deposition process and the chemical vapor reaction process successively, however, reaction gas needs to be supplied onto the substrate surface at as constant a concentration as possible. For this reason, the reaction gas outlet of the gas dispersion plate needs to have a constant surface density. To supply reaction gas at a constant concentration, the pressure in the gas dispersion chamber inside the showerhead needs to be set greater than the pressure in the reaction space. Accordingly, the vacuum conductance of the dispersion plate at the showerhead decreases. On the other hand, if this dispersion plate is used for atomic layer deposition, the small vacuum conductance of the dispersion plate necessitates a longer time to discharge reaction gas from the dispersion chamber in the showerhead, which is a drawback for the atomic layer deposition apparatus.

In one embodiment of the present invention, one object is to implement atomic layer deposition and chemical vapor deposition consecutively using the same reaction apparatus in order to form high-quality film not heretofore achievable, and therefore a thin-film formation apparatus and thin-film formation method are provided to achieve the above object. According to another embodiment, in a process where chemical vapor deposition and plasma post-processing are repeated, the same thin-film formation method can be applied to form high-quality thin film at higher productivity. Film formed continuously via chemical vapor deposition tends to contain impurities. However, in the case of plasma ALD, repeated plasma processing (e.g. repetition of the steps: supplying material, purging, hydrogen plasma, and purging) reduces impurities (impurities are further reduced because the impurities in the film are further decomposed and discharged by the repeated plasma processing), thus enabling formation of high-quality film.

In an embodiment which can achieve at least one of the above objectives, the present invention provides a method for forming a thin film on a substrate using a showerhead comprising an upper compartment and a lower compartment which is disposed underneath and overlapped by the upper compartment as viewed in an axial direction of the showerhead and is not gas-communicated with the upper compartment, wherein a surface of the showerhead facing a susceptor has an overlapping region in which the upper compartment and the lower compartment are overlapped as viewed in the axial direction of the showerhead, and in the overlapping region, the showerhead has first bores being gas-communicated with the upper compartment without being gas-communicated with the lower compartment, and second bores being gas-communicated with the lower compartment without being gas-communicated with the upper compartment, said method comprising the steps of: (i) discharging a first gas from the upper compartment through the first bores of the showerhead into a reaction space toward a substrate on the susceptor; (ii) after step (i), discharging a second gas from the lower compartment through the second bores of the showerhead into the reaction space toward the substrate; (iii) repeating preceding steps including steps (i) and (ii) to form a first film on the substrate; and (iv) discharging a third gas and a fourth gas from the upper compartment through the first bores and the lower compartment through the second bores, respectively, to form a second film on the first film which is different from the first film.

The above embodiment includes, but is not limited to, the following embodiments:

The method may further comprise step (ia) of purging the upper compartment with a purge gas between steps (i) and (ii). In the above, the upper compartment may be provided with an exhaust port for evacuating predominantly the upper compartment, and the method may further comprise step (ib) of evacuating the upper compartment through the exhaust port between steps (ia) and (ii).

The method may further comprise step (iia) of purging the lower compartment with a purge gas between steps (ii) and (iii). In the above, the lower compartment may be provided with an exhaust port for evacuating predominantly the lower compartment, and the method may further comprise step (iib) of evacuating the lower compartment through the exhaust port between steps (iia) and (iii).

In an embodiment, step (iv) may further comprise applying RF power to the reaction space.

In an embodiment, the first film may be constituted by a thermal or plasma atomic layer deposition film. The second film may be constituted by a thermal or plasma chemical vapor deposition film. In an embodiment, the second film may be constituted by a thermal or plasma atomic layer deposition film. In an embodiment, the first gas and the third gas may be the same gas. The second gas and the fourth gas may be the same gas. Further, in an embodiment, the upper compartment may have a gas inlet port positioned in its center through which the first gas and the third gas are supplied to the upper compartment. The lower compartment may have a gas inlet port positioned at its periphery through which the second gas and the fourth gas are supplied to the lower compartment.

In an embodiment, the method may further comprise step (iic) of applying RF power to the second gas between steps (i) and (ii).

In an embodiment, step (iv) may comprise: (iva) discharging the third gas from the upper compartment through the first bores of the showerhead into the reaction space toward the substrate; (ivb) after step (iva), discharging the fourth gas from the lower compartment through the second bores of the showerhead into the reaction space toward the substrate; (ivc) applying RF power to the fourth gas; and (ivd) repeating preceding steps in step (iv) including steps (iva) through (ivc) to form the second film on the first film.

In another embodiment, step (iv) may comprise: (iva) discharging the third gas from the upper compartment through the first bores of the showerhead into the reaction space toward the substrate; (ivb) purging the upper compartment with a purge gas; (ivc) discharging a fifth gas from the upper compartment through the first bores of the showerhead into the reaction space toward the substrate; (ivd) applying RF power to the fifth gas; and (ive) repeating preceding steps in step (iv) including steps (iva) through (ivd) to form the second film on the first film.

In an embodiment, the substrate may have an insulation layer on which the first film is formed. In an embodiment, the first film and/or second film may contain ruthenium.

In an embodiment which can achieve at least one of the aforesaid objectives, the present invention provides a method for forming a thin film on a substrate using a showerhead comprising an upper compartment and a lower compartment which is disposed underneath and overlapped by the upper compartment as viewed in an axial direction of the showerhead and is not gas-communicated with the upper compartment, wherein a surface of the showerhead facing a susceptor has an overlapping region in which the upper compartment and the lower compartment are overlapped as viewed in the axial direction of the showerhead, and in the overlapping region, the showerhead has first bores being gas-communicated with the upper compartment without being gas-communicated with the lower compartment, and second bores being gas-communicated with the lower compartment without being gas-communicated with the upper compartment, said method comprising the steps of: (i) discharging a first gas from the upper compartment through the first bores of the showerhead into a reaction space toward a substrate on the susceptor; (ii) discharging a second gas from the lower compartment through the second bores of the showerhead into the reaction space toward the substrate; (iii) optionally applying RF power to the reaction space, thereby forming a first film on the substrate; and (iv) discharging a third gas from at least one of the upper compartment through the first bores and the lower compartment through the second bores to treat a surface of the first film on the substrate.

The above embodiment includes, but is not limited to, the following embodiments.

The method may further comprise step (ia) of purging the upper compartment with a purge gas between steps (i) and (iv). In the above, the upper compartment may be provided with an exhaust port for evacuating predominantly the upper compartment, and the method may further comprise step (ib) of evacuating the upper compartment through the exhaust port between steps (ia) and (iv).

The method may further comprise step (iia) of purging the lower compartment with a purge gas between steps (ii) and (iv). In the above, the lower compartment may be provided with an exhaust port for evacuating predominantly the lower compartment, and the method may further comprise step (iib) of evacuating the lower compartment through the exhaust port between steps (iia) and (iv).

In an embodiment, step (iv) may further comprise exciting the third gas to treat the surface of the first film of the substrate. The excitation of the third gas may be performed by heat or plasma. In an embodiment, steps (i) through (iv) may be repeated.

In an embodiment, step (iv) may comprise (iva) discharging the third gas from the upper compartment through the first bores of the showerhead into the reaction space toward the substrate; (ivb) after step (iva), discharging a fourth gas from the lower compartment through the second bores of the showerhead into the reaction space toward the substrate; (ivc) repeating preceding steps including steps (iva) and (ivb) to form a second film on the first film on the substrate as the treatment of the first film.

In an embodiment, the first film may be constituted by a thermal or plasma chemical vapor deposition film. The second film may be constituted by a thermal or plasma atomic layer deposition film. In an embodiment, there may be substantially no second film but the surface of the first film may be subjected to surface treatment.

In all of the aforesaid embodiments, any element used in an embodiment can interchangeably or additionally be used in another embodiment unless such a replacement is not feasible or causes adverse effect. Further, two or more embodiments can be used in any suitable combinations. Further, the present invention can equally be applied to apparatuses and methods.

For purposes of summarizing the invention and the advantages achieved over the related art, certain objects and advantages of the invention are described in the present disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention.

FIG. 1(a) is a schematic drawing showing a cross-section view of the apparatus used in the thin-film formation process in one embodiment of the present invention. FIG. 1(b) is a schematic drawing showing a perspective view of the dispersion nozzle that can be used in the present apparatus.

FIG. 2 is a flowchart of the thin-film formation process in one embodiment of the present invention.

FIG. 3 is a flowchart of the thin-film formation process in another embodiment of the present invention.

FIG. 4(a) and FIG. 4(b) show the shower plate (post-mix type showerhead) used in the thin-film formation process in one embodiment of the present invention. FIG. 4(a) is a perspective cross-section view of a part of the showerhead, while FIG. 4(b) is a cross-section view of the showerhead.

FIG. 5 shows an example of a valve operation in the process when the process flow chart of FIG. 2 is carried out using a reaction apparatus having a structure shown in FIG. 1.

FIG. 6 shows an example of a valve operation in the process when the process flow chart of FIG. 3 is carried out using a reaction apparatus having a structure shown in FIG. 1.

### DESCRIPTION OF THE SYMBOLS

1: Chamber
2: Substrate heating base (also called support or susceptor)
3: Exhaust duct
4: Shower plate (also called dispersion plate or showerhead)
5: Gas inlet to the lower gas dispersion chamber
6: Gas outlet from the lower gas dispersion chamber (also called second bores)
7: Lower gas dispersion chamber (also called second dispersion chamber or second compartment)
8: Gas guide of the upper gas dispersion chamber
9: Exhaust valve of the upper gas dispersion chamber
10: Gas-mixing center gas pipe
11: Gas dispersion plate nozzle
12: Gas outlet from the upper gas dispersion chamber (also called first bores)
13: Upper lid plate
14: Substrate
15: Bellows for moving the substrate heating base up/down
16: Gate valve
17: Upper dispersion chamber (also called first dispersion chamber or first compartment)
18: Showerhead surface (including common discharging region (also called overlapping region) of upper and lower dispersion chambers)
19: Reaction region (also called reaction space)
20: Material gas A purge valve
21: Material gas A introduction valve
22: Purge gas for gas-mixing center gas pipe
23: Material gas B purge gas valve
24: Material gas B introduction valve
25: Main exhaust valve
26: Pressure control part
27: Molecular pump gate valve
28: Evaluation gate valve
29: Molecular pump
30: Dry pump
31: Bellows-purge gas introduction valve
32: Exhaust valve connected to the dispersion chamber 7
33: RF introduction terminal

### DETAILED DESCRIPTION OF THE PREFERRED EMBODIMENT

In an embodiment of the present invention, the combination of ALD (thermal, plasma) and CVD (thermal, plasma) becomes possible. This can be carried out with an apparatus that has a function required for ALD process and a function required for CVD. The apparatus is capable of uniform gas dispersion for CVD, and also equipped with multiple dispersion chambers. In this case, the apparatus is applicable to ALD and CVD by being provided with an exhaust valve in a dispersion chamber in order to be applicable to ALD process which requires frequent replacement of gas in the dispersion chamber, thereby a consecutive process of ALD and CVD becomes possible.

In another embodiment, as in the case where plasma heat treatment is often performed in CVD process, in the case where the reaction gas is discharged in a short time and the plasma treatment is performed after carrying out CVD, a repetition speed can be improved by using exhaust valve provided in the dispersion chamber.

In addition, in an embodiment, since film forming in the dispersion chamber and impurity generation are prevented by using multiple dispersion chambers in thermal ALD, it is also effective in thermal ALD+plasma ALD. In this case, because plasma is not generated in the dispersion chamber, a film is not formed in the dispersion chamber during ALD. Thus, multiple dispersion chambers do not necessarily need to be used.

The present invention will be explained with respect to preferred embodiments. However, the present invention is not limited to the preferred embodiments.

One embodiment of the present invention provides, using a thin-film formation apparatus, comprising a gas supply apparatus configured to be connected to an evacuatable reaction chamber provided with a susceptor for placing a substrate thereon, and a gas dispersion head to introduce gas into the chamber through a head surface, comprising a first section to discharge gas through the head surface in the direction of a support (susceptor), and a second section to discharge gas through the head surface in the direction of the support, wherein the first and second sections are separately superposed from each other in the gas dispersion head so as not to have a gas passage, and wherein the first section is connected to an exhaust system for purging therefrom a gas present in the corresponding section without passing through the head surface: a thin-film formation method characterized by comprising as the process for forming thin film: a step to discharge reaction gas A from the first section; a step to stop reaction gas A and open an open/close valve connected to the first section and exhaust side; a step to introduce purge gas into the first section; a step to discharge reaction gas B from the second section; a step to stop reaction gas B and introduce purge gas into the second section, where the aforementioned steps are repeated to form a first thin film on the substrate (these steps are hereinafter collectively referred to as the atomic layer deposition process); and a step to discharge reaction gas C from the first section and reaction gas D from the second section to implement chemical vapor deposition on the substrate surface to form a second thin film on the first thin film (this step is hereinafter referred to as the chemical vapor deposition process).

Another embodiment of the present invention provides, using a thin-film formation apparatus, comprising a gas supply apparatus configured to be connected to an evacuatable reaction chamber provided with a susceptor for placing a substrate thereon, and a gas dispersion head to introduce gas into the chamber through a head surface, comprising a first section to discharge gas through the head surface in the direction of a support, and a second section to discharge gas through the head surface in the direction of the support (susceptor), wherein the first and second sections are separately superposed from each other in the gas dispersion head so as not to have a gas passage, and wherein the first and second sections are connected to an exhaust system for purging therefrom a gas present in the corresponding section without passing through the head surface: a thin-film formation process and a thin-film formation method characterized by comprising as the process for forming thin film: a step to discharge reaction gas A from the first section; a step to stop reaction gas A and open an open/close valve connected to the first section and exhaust side; a step to introduce purge gas into the first section; a step to discharge reaction gas B from the second section; a step to stop reaction gas B and open an open/close valve connected to the second section and exhaust side; a step to introduce purge gas into the second section, where the aforementioned steps are repeated to form a first thin film on the substrate (these steps are hereinafter collectively referred to as the atomic layer deposition process); and a step to discharge reaction gas C from the first section and reaction gas D from the second section to implement chemical vapor deposition on the substrate surface to form a second thin film on the first thin film (this step is hereinafter referred to as the chemical vapor deposition process).

Yet another embodiment of the present invention provides, using a thin-film formation apparatus, comprising a gas supply apparatus configured to be connected to an evacuatable reaction chamber provided with a susceptor for placing a substrate thereon, and a gas dispersion head to introduce gas into the chamber through a head surface, comprising a first section to discharge gas through the head surface in the direction of a support (susceptor), and a second section to discharge gas through the head surface in the direction of the support, wherein the first and second sections are separately superposed from each other in the gas dispersion head so as not to have a gas passage, and wherein the first section is connected to an exhaust system for purging therefrom a gas present in the corresponding section without passing through the head surface, a thin-film formation method characterized by including as the process for forming thin film: a step to discharge reaction gas A from the first section and reaction gas B from the second section for a specified time and implement chemical vapor deposition on the substrate surface to form a first thin film; a step to open an exhaust valve connected to the first section to discharge the reaction gas A, discharge reaction gas B from the second section, and then introduce purge gas into each of the sections; and a step to discharge reaction gas C from at least either the first section or second section for a specified time, after which reaction gas C is stopped and discharged, and then purge gas is introduced into the sections.

Yet another embodiment of the present invention provides, using a thin-film formation apparatus, comprising a gas supply apparatus configured to be connected to an evacuatable reaction chamber provided with a susceptor for placing a substrate thereon, and a gas dispersion head to introduce gas into the chamber through a head surface, comprising a first section to discharge gas through the head surface in the direction of a support (susceptor), and a second section to discharge gas through the head surface in the direction of the support, wherein the first and second sections are separately superposed from each other in the gas dispersion head so as not to have a gas passage, and wherein the first section is connected to an exhaust system for purging therefrom a gas present in the corresponding section without passing through the head surface: a thin-film formation method characterized by including as the process for forming thin film: a step to discharge reaction gas A from the first section and reaction gas B from the second section for a specified time and implement chemical vapor deposition on the substrate surface to form a first thin film; a step to open an exhaust valve connected to the first section and an exhaust valve connected to the second section to discharge the reaction gases A, B and then introduce purge gas into each of the sections; and a step to discharge reaction gas C from at least either the first section or second section for a specified time, after which reaction gas C is stopped and discharged, the exhaust valve connected to either the first or second section is opened to discharge reaction gas C, and then purge gas is introduced into the sections.

One favorable embodiment of the present invention uses the aforementioned thin-film formation apparatus described in U.S. patent application Ser. No. 10/824,798 to solve the problem of low productivity associated with the conventional atomic layer deposition process. However, the aforementioned apparatus need not always be used and any other apparatus can be used as long as such other apparatus provides the same function.

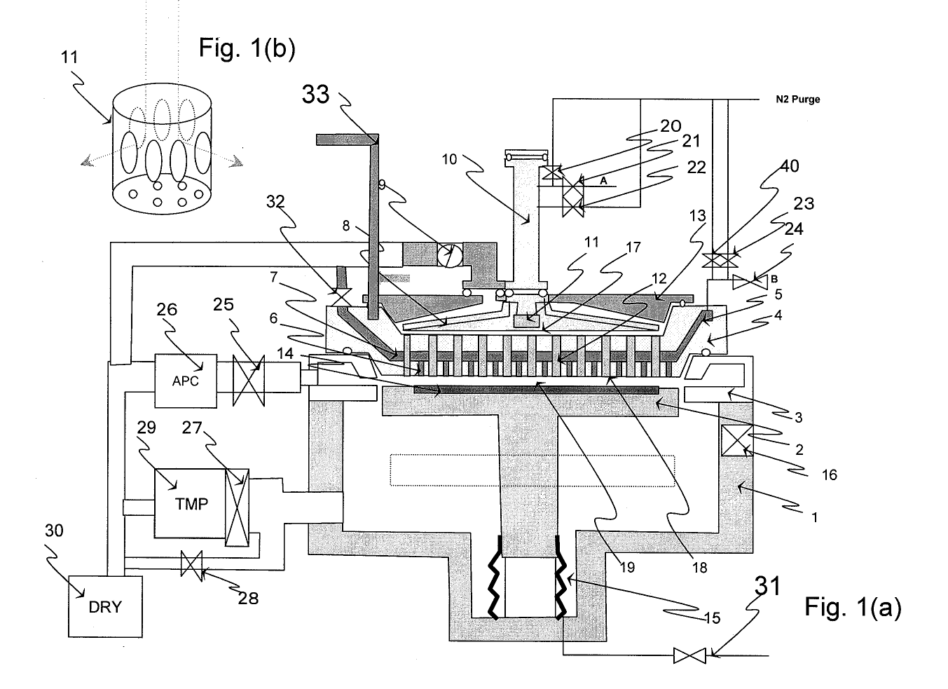

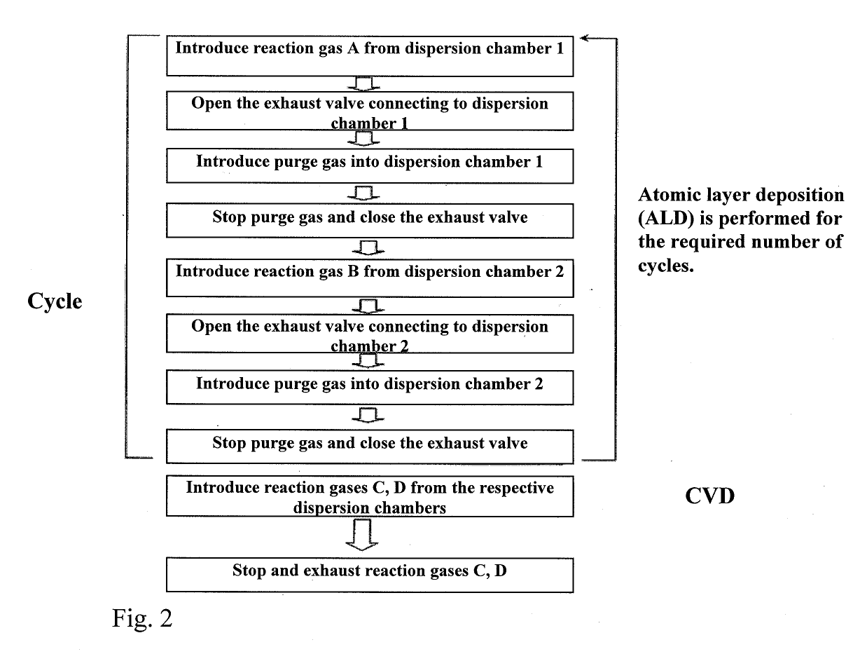

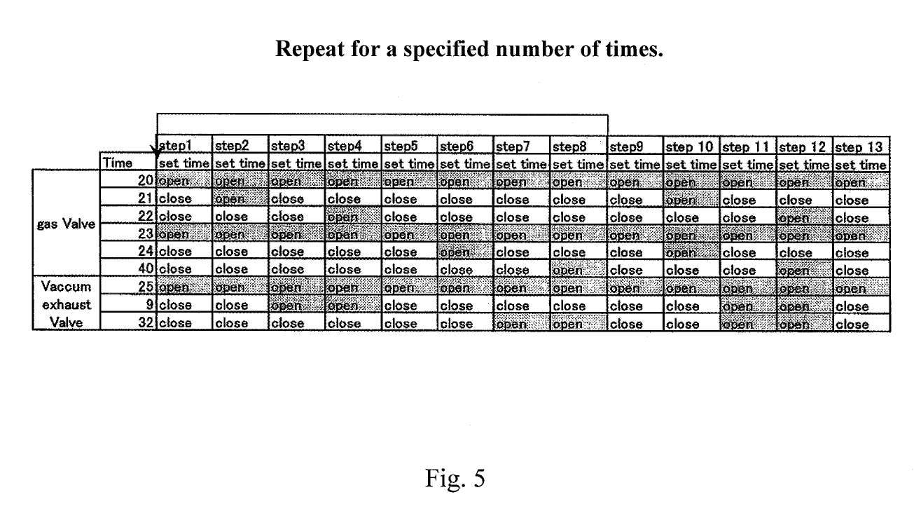

FIG. 1(a) is a schematic drawing showing the configuration of the apparatus that can be used in an embodiment of the present invention. FIG. 1(b) is a schematic drawing showing the configuration of the gas dispersion nozzle that can be used in the apparatus of FIG. 1(a). FIG. 2 is an example of flowchart of the chemical vapor deposition process performed after atomic layer deposition using the apparatus in FIG. 1(a). First, one cycle of the atomic layer deposition process shown in FIG. 2, consisting of a material gas A supply step, exhaust/purge step, reaction gas B supply step, and exhaust/purse step, is repeated for a specified number of times, after which reaction gases C, D are supplied simultaneously to perform chemical vapor deposition for a specified time, upon which the thin-film formation process ends. FIG. 5 summarizes an example of the operations of valves shown in FIG. 2. By using the exhaust valves 9, 32 directly connected to the showerhead, which comprise one key feature of an embodiment of the present invention, the purge time of reaction gas can be reduced substantially. In the chemical vapor deposition process, the diameter and number of pores in the gas outlet of the dispersion plate can be optimized to enable formation of uniform thin film. Similarly, use of the apparatus configuration shown in FIG. 1(a) achieves a more productive process not heretofore feasible with conventional apparatuses.

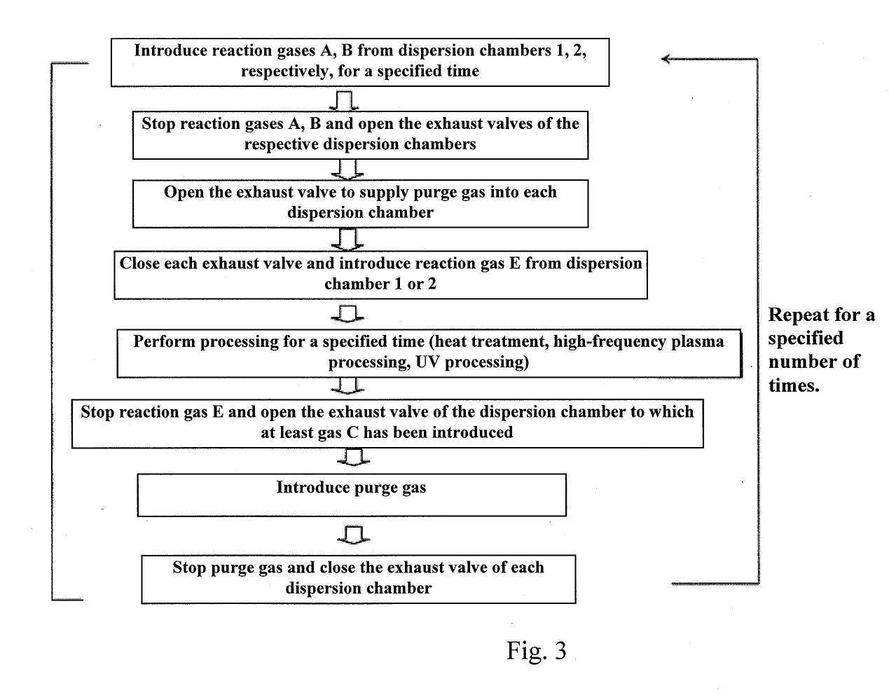

FIG. 3, which shows another embodiment of the present invention, illustrates an example of a method to not only improve productivity, but also to improve film quality while maintaining high productivity. After thin film of a specified film thickness is formed by chemical vapor reaction, the exhaust valve connected to each dispersion chamber (section) in the showerhead is opened and purge gas is introduced into each dispersion chamber to quickly purge reaction gases A, B, after which reaction gas E is introduced to either dispersion chamber to improve the quality of formed film. At this time, reaction gas E may be caused to act upon formed film by means of thermal reaction; or reaction gas E may be activated by high-frequency plasma excitation and then caused to act upon film; or reaction gas E may be caused to act upon thin film under irradiation of ultraviolet light. After any of these processes, reaction gas E is discharged from the dispersion chamber, where the gas E has been introduced into, through the exhaust valve connected to the showerhead, after which purge gas is introduced into the dispersion chamber to ensure quick discharge of reaction gas. The aforementioned thin-film formation and film-quality improvement processing comprises one cycle and this cycle is repeated to achieve efficient improvement of film quality, thus realizing significant productivity improvement.

According to the method described above, if the cycle is repeated 30 times, for example, the purge time can be reduced to 1 second instead of 10 seconds in the thin-film formation process whose duration is set to 3 seconds, and this difference in purge time results in a substantial productivity gain. According to the method proposed by the present invention, the conductance of the exhaust valve connected to each dispersion chamber in the showerhead is several times to approx. one digit greater than (2-100 times, or 5-30 times, for example) the conductance of the dispersion plate constituting the shower plate, while purge gas can be supplied at a flow rate several times greater than (2-100 times, or 5-30 times, for example) the flow rate of reaction gas to reduce the purge time to around 1 second in a setting that traditionally requires 10 seconds of purge. As a result, the cycle shown in FIG. 3 can achieve a rational productivity level when implemented by the thin-film formation apparatus proposed by the present invention.

The above explained an embodiment using reaction gases A, B, C, D, E. The examples shown in FIG. 2 and FIG. 3 are explained using specific examples of reaction gases. For example, in the case of an embodiment shown in FIG. 2, gas A is WF6, gas B is NH3, gas C is WF6, and gas D is NH3 in the formation of WN film. In the case of an embodiment shown in FIG. 3, gas E is N2/H2 or NH3 and excited by RF plasma. When forming TiN film, it is possible to set gas A as TiCl4, gas B as NH3, gas C as TiCl4, and gas D as NH3, for example. Gas E is NH3 or N2/H2 gas to which RF plasma may be applied, for example. In the formation of Ru film, gas A is organic metal material gas of Ru, while gas B is NH3 gas to which RF plasma is applied. In an embodiment, gas C is organic metal material gas of Ru, while gas D is oxygen. O2 gas may be used as gas E. Cyclopentadienyls of cyclic compounds including cyclopentadienyl(Cp), methylcyclopentadienyl(MeCp), and ethylcyclopentadienyl(EtCp), for example, which are disclosed in the US Publication No. 2006/0177601A1, Ru raw material having isopropylcyclopentadienyl(i-PrCp), or Ru raw material disclosed in the U.S. application Ser. No. 11/557,891 by the same applicant as the present application in which the Ru material having a molecular structure of Ru(XaXb) where at least either Xa or Xb is acyclic pentadienyl, can be used as an organic metal material of Ru, for example. (the disclosure of the above publication and application is incorporated herein by reference in their entirety)

As explained above, the processes illustrated by the process charts in FIGS. 2 and 3 can be applied to form various thin film materials at favorable productivity. Examples of the treatment conditions concerning FIGS. 2-3 are indicated below. Nevertheless, these conditions is not intended to limit the present invention.

TABLE 1
Examples of process conditions concerning FIGS. 2

| | |
|---|---|
| Number of ALD cycle | 50-100, preferably 50-100 |
| ALD film thickness (nm) | 1-5, preferably 1-3 |
| Reaction gas A | For WN film: WF6, |
| | For WNC film: WF6 |
| | For TaN film: TaF5 |
| | For TaNC film: Taimata |
| | For TiN film: TiCl4 |
| | For Ru film: Ru(EtCp)2 |
| Flow of reaction gas A (sccm) | 1-100, preferably 1-10 |
| Supply time of reaction gas A (sec) | 0.1-2, preferably 0.5-1.0 |
| Purge gas | N2 |
| Flow of purge gas (sccm) | 500-2000, preferably 1000-2000 |
| Supply time of purge gas (sec) | 0.1-10, preferably 0.5-1 |
| Reaction gas B | For WN film: NH3 |
| | For WNC film: NH3, (C2H5)3B |
| | For TaN film: NH3 |
| | For TaNC film: H2 |
| | For TiN film: NH3 |
| | For Ru film: NH3 |
| Flow of reaction gas B (sccm) | 100-1000, preferably 200-500 |
| Supply time of reaction gas B (sec) | 1-10, preferably 1-2 |
| Application of RF | (plasma ALD only) |
| | Wavelength (MHz): 13.56 |
| | Electricity (W): 200-1000, preferably 300-700 |
| Purge gas | Argon, Nitrogen |
| Flow of purge gas (sccm) | 100-2000, preferably 1000-2000 |
| Supply time of purge gas (sec) | 0.5-2, preferably 0.5-1 |
| Reaction gas C | For WN film: H2, NH3 |
| | For WNC film: H2, NH3 |
| | For TaN film: H2, NH3 |
| | For TaNC film: H2, NH3 |
| | For TiN film: H2, NH3 |
| | For Ru film: O2 |
| Flow of reaction gas C (sccm) | 100-2000, preferably 300-1000 |
| Reaction gas D | For WN film: WF6 |
| | For WNC film: W(CO)6 |
| | For TaN film: TaF5 |
| | For TaNC film: Taimata |
| | For TiN film: TiCl4 |
| | For Ru film: Ru(EtCp)2 |
| Flow of reaction gas D (sccm) | 0.1-100, preferably 1-10 |
| Application of RF | Wavelength (MHz): 13.56 |
| | Electricity (W): 200-1000, preferably 300-700 |
| CVD reaction time (sec) | 30-600, preferably 60-200 |
| CVD film thickness (nm) | 1-100, preferably 1-50 |

TABLE 2
Examples of process conditions concerning FIGS. 3

| | |
|---|---|
| Number of cycle | 1 cycle-several cycles |
| Film thickness (nm) | 1-10, preferably 1-2 |
| Film forming time (sec) | 1-200, preferably 2-10 |
| Reaction gas A | For WN film: WF6 |
| | For WNC film: W(CO2)6 |
| | For TaN: TaF5 |
| | For TaNC: Taimata |
| | For TiN: TiCl4 |
| | For Ru: Ru(EtCp)2 |
| Flow of reaction gas A (sccm) | 1-100, preferably 1-30 |
| Reaction gas B | For WN film: NH3 |
| | For WNC film: NH3 |
| | For TaN film: NH3 |
| | For TaNC film: H2 or NH3 |
| | For TiN film: NH3 |
| | For Ru film: O2 |
| Flow of reaction gas B (sccm) | 100-1000, preferably 100-500 |
| Reaction gas E | For heat treatment: H2 |
| | For RF plasma treatment: H2, NH3 |
| | For UV treatment: N2 |
| Flow of reaction gas E (sccm) | 100-2000, preferably 100-1000 |
| Heat treatment conditions | Temperature (° C.): 200-600, preferably 200-400 |
| | Time (min): 0.5-5, preferably 0.5-2 |
| RF plasma treatment conditions | RF frequency (MHz): 13.56 MHz |
| | RF electricity (W): 100-1000, preferably 300-500 |
| | Time (min): 0.1-10, preferably 0.1-2 |
| UV treatment conditions | Wavelength (nm): 170-300, preferably 170-200 |
| | Electricity (W): 100-1000, preferably 200-500 |
| Purge gas | Argon |
| Flow of purge gas (sccm) | 100-2000, preferably 500-1000 |

The present invention includes the above embodiments and their combinations. The present invention is not limited by these embodiments. Further, each process condition can be carried out by the combination of above Table. 1 and Table. 2.

(1) The first film (ALD)+the second film (CVD)

(2) The first film is thermal ALD in the above-mentioned (1).

(3) The first film is plasma CVD in the above-mentioned (1).

(4) The second film is thermal CVD in the above-mentioned (1).

(5) The second film is plasma ALD in the above-mentioned (1).

(6) The first film (CVD)+Surface treatment

(7) The first film is thermal CVD in the above-mentioned (6).

(8) The first film is plasma CVD in the above-mentioned (6).

(9) Repeat (the first film (CVD)+Surface treatment) in the above-mentioned (6).

(10) Surface treatment with an active gas in the above-mentioned (6).

(11) Surface treatment is ALD film forming treatment in the above-mentioned (6).

(12) The first film (ALD)+the second film (ALD).

(13) The first film is thermal ALD in the above-mentioned (12).

(14) The first film is plasma ALD in the above-mentioned (12).

(15) The second film is thermal ALD in the above-mentioned (12).

(16) The second film is plasma ALD in the above-mentioned (12).

FIG. 2 corresponds to combination of the above (2)+(5). FIG. 3 corresponds to the above (7). Forming film of the first and the second film can be carried out using the first dispersion chamber and the second dispersion chamber which do not have gas passage between them. Further, the combination of (13)+(16) can be performed by discharging the gas for plasma used for plasma ALD from at least either the first dispersion chamber or the second dispersion chamber. Further, the above (6) can be performed by discharging the gas for surface treatment at least from either the first dispersion chamber or the second dispersion chamber. Furthermore, in the above (1), (6), and (12), there are an embodiment wherein exhaust is from the first dispersion chamber and another embodiment wherein exhaust is from the second dispersion chamber.

The configuration of the thin-film formation apparatus concerning an embodiment of the present invention is explained below using the drawings. Nevertheless, these drawings do not limit the present invention.

In the thin-film formation apparatus of FIG. 1, the processing target, or a semiconductor substrate, can be transferred from a vacuum transfer chamber (not illustrated) into a reaction chamber 1 through a gate valve 16 to implement the thin-film formation process in this reaction chamber 1. A transferred substrate 14 is placed on a heating base 2, while the gas is exhausted through a valve 27 with a molecular pump 29 (TMP). (valve 28 is also provided so that exhaust can be performed with vacuum pump 30). Thereafter, the substrate heating base 2 is raised using bellows 15 until an optimal distance is achieved from a shower plate. As a result, reaction gas supplied from the shower plate is supplied onto the surface of the substrate 14 and then discharged via an exhaust duct 3. At this time, a valve 31 is opened to supply inactive gas in order to prevent the reaction gas supplied from the shower plate 4 from being dispersed toward the transfer side where the bellows 15 are located.

This reaction chamber comprises the exhaust duct 3, a shower plate 4 and an upper lid 13 placed on top of each other, while a gas dispersion nozzle 11 (FIG. 1(b) shows a schematic drawing of the structure) and a gas dispersion guide 8 are located between the shower plate 4 and upper lid 13 in a manner connecting to a gas introduction pipe 10. Furthermore, an exhaust valve 9 for exhausting the dispersion part is connected along the gas dispersion guide. Also, the shower plate 4 is connected to a gas introduction part 5, a gas introduction valve 24 and a gas exhaust valve 32. An inactive gas introduction valve 23 used for purge is also connected. In addition, a gas introduction valve 21 and an inactive gas introduction valve 20 used for purge are connected to the gas introduction pipe 10. Material gas is introduced from the valve 21. A valve 22 for introducing a large amount of inactive gas is also formed. Gas A introduced through the valve 21 into the gas introduction pipe 10 is dispersed by the gas dispersion nozzle 11, travels along the gas dispersion guide 8, and is finally supplied onto the substrate 14 through gas outlet pores 12 passing through the enter width of the shower plate 4. Gas B supplied from the gas valve 24 travels through the gas introduction part 5 provided inside the shower plate 4 to be dispersed inside a gas dispersion chamber 7 and eventually supplied onto the substrate 14 through gas outlet pores 6. Gas supplied onto the substrate 14 travels through the exhaust duct 3, an exhaust valve 25 and a pressure control device (APC) 26, to be exhausted by a vacuum pump 30. When purging reaction gas, on the other hand, inactive gas is introduced from the gas valves 20, 22, and the valve 9 is opened to exhaust residual gas A from the exhaust valve 9. At this time, residual gas A is also exhausted from the exhaust duct 3 through the gas outlet pores 12, but since the exhaust conductance of the valve 9 is set at least one digit higher (2-100 times, or preferably 5-30 times, for example), most residual gas will be exhausted through the exhaust valve 9. To purge gas B supplied from the gas valve 24, similarly inactive gas is introduced from the valve 23 (valve 40 is also provided for introducing a large quantity of inactive gas) and the exhaust valve 32 is opened to discharge residual gas. At this time, some residual gas is exhausted from the exhaust duct 3 through the gas outlet pores 6, but the larger conductance of the gas exhaust valve 32 (2-100 times, or preferably 5-30 times) compared to that of the gas outlet pores 6 causes most residual gas to be discharged through the exhaust valve 32.

By utilizing the aforementioned functions, a process apparatus best suited for the atomic layer deposition process where reaction gases A, B are supplied alternately, or for the layer-by-layer thin-film formation process, can be provided.

Also, chemical vapor deposition can be implemented by supplying gases A, B simultaneously. In this case, material A supplied from the valve 21 is supplied onto the substrate surface through the gas outlet pores 12, while material B supplied from the valve 24 is supplied onto the substrate surface through the gas outlet pores 6. Gas A reacts with gas B on the substrate surface to cause chemical vapor reaction, resulting in formation of thin film.

FIG. 2 shows the procedure of thin-film formation process in an embodiment of the present invention. A two-stage process may be implemented, where atomic layer deposition is performed for a specified number of times first, and then chemical vapor reaction is performed. FIG. 3 shows a process in which this two-stage process is repeated, where chemical vapor reaction is followed by some kind of processing performed on thin film.

FIG. 5 shows an example of a gas introduction sequence when the thin-film formation process in FIG. 2 is performed using the apparatus in FIG. 1. These process steps correspond to atomic layer deposition using reaction gases A, B, followed by chemical vapor deposition also using reaction gases A, B. As the basic sequence, representative valve operations for alternate introduction of gases A, B are shown. The valves 20, 21 are used for inactive gas or N2 gas and reaction gas A, respectively. The valve 22 is a large-capacity purge gas valve for purging reaction gas from the showerhead, while the valves 23, 24 are used for inactive gas or N2 and reaction gas B, respectively. The valve 25 is an exhaust valve for the reaction chamber, while the valves 9, 32 are exhaust valves connected to the dispersion chambers in the showerhead into which reaction gases A, B are introduced, respectively.

In step 1, reaction gases A, B are not supplied to the showerhead, but only N2 gas is introduced and exhausted from the exhaust valve 25. In step 2, reaction gas A is supplied to the showerhead. In step 3, supply of reaction gas A is stopped, while the valve 9 is opened to quickly discharge reaction gas A in the showerhead. In step 4, a large amount of purge gas is introduced from the valve 22, and then residual reaction gas A is discharged further. In step 5, introduction of large amount of purge gas is stopped, and then purge gas is exhausted. In step 6, reaction gas B is supplied to the showerhead. In step 7, supply of reaction gas B is stopped, while the valve 32 is opened to quickly discharge reaction gas B in the showerhead. In step 8, the valve 40 is opened, purge gas is introduced, and then the remaining reaction gas B is further discharged. These steps 1 through 8 are repeated for a specified number of times, and in subsequent steps 9 and 10 chemical vapor reaction is performed, in the exhaust mode in step 9 and while supplying reaction gas A and reaction gas B simultaneously in step 10. In step 11, reaction gas in the showerhead is discharged from the valves 9, 32, and in step 12 purge gas is supplied to the respective dispersion chambers in the showerhead to purge reaction gas. In step 13, purge gas is stopped and the showerhead exhaust valve is closed. By using this sequence, it is possible to form 18 nm of WN film via the CVD method consecutively after forming 2 nm of film by the 20-cycle atomic layer deposition method, where the quick deposition speed under CVD enhances productivity.

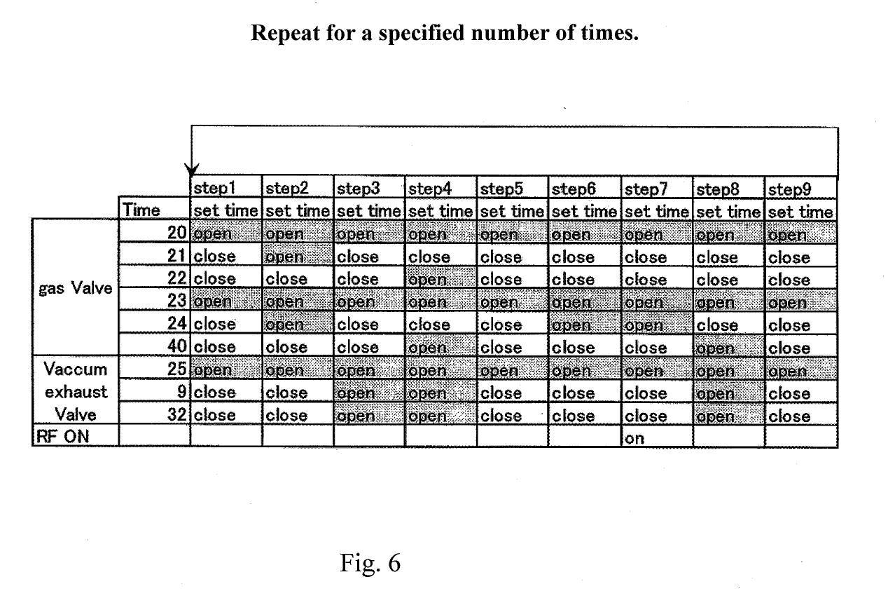

FIG. 6 shows an example of the valve operations to perform the process flow shown in FIG. 3. Step 1 corresponds to the condition before starting the process, while in step 2 reaction gases A, B are supplied to the showerhead simultaneously to form thin film via chemical vapor deposition. In step 3, reaction gas is stopped and the showerhead exhaust valve is opened to discharge reaction gas. In step 4, purge gas is introduced to fully purge reaction gas. In step 5, purge gas is stopped and the exhaust valve is closed. Next in step 6, only reaction gas B is supplied to the showerhead, while in step 7 RF plasma is applied to reform thin film for a specified time. In step 6, different reaction gas E may be introduced. In this reforming process, optimal processing can be performed, such as performing gas processing only or implementing high-frequency plasma application or UV light irradiation. Next in step 8, reaction gas B or E is stopped and the showerhead exhaust valve is opened to discharge reaction gas, and then purge gas is introduced to fully discharge reaction gas. In step 9, the sequence returns to the condition in step 1. By repeating these process steps 1 through 9, thin film of extremely high quality can be formed at high productivity.

In the present disclosure where conditions and/or structures are not specified, the skilled artisan in the art can readily provide such conditions and/or structures, in view of the present disclosure, as a matter of routine experimentation.

The effects of the present invention are explained below using specific examples. These examples do not limit the present invention.

### EXAMPLE 1

Here, an example of implementing a specific process using a process apparatus of the structure shown in FIG. 1 is explained. This example specifically refers to the formation of Ru film using bis(ethylcyclopentadienyl)ruthenium [Ru(C5H4C2H5)2] (hereinafter referred to as Ru(EtCp)2) and ammonium (hereinafter referred to as NH3). A silicon substrate is transferred into the reaction chamber 1 from a vacuum transfer chamber (not illustrated), after which the residual water, oxygen, etc., are fully discharged using a turbo pump 29. Next, the substrate is moved to a specified position by means of the up/down mechanism of the substrate heating base 2. At this time, the gap between the showerhead plate 4 and substrate surface is set to a range of 20 mm to 8 mm. In this example, the process was performed with this gap adjusted to 20 mm.

The example followed the sequence of the process in FIG. 5. The reaction chamber is exhausted using the exhaust duct 3. At this time, the distance between the substrate heating base 2 and exhaust duct 3 is reduced so that reaction gas is mostly exhausted from the exhaust duct 3. The substrate heating base 2 and exhaust duct 3 can be contacted with each other to close any gap in between. In this example, however, the distance between the substrate heating base 2 and exhaust duct 3 was reduced (non-contacting distance during the operation, clearance of approximately 1 mm-3 mm, for example), while the pressure in the transfer space was differential-pressure controlled to 10-100%, or preferably 10-20% higher than the pressure on the substrate (controlled to 1.1-1.2 Torr when the reaction region is 1 Torr, for example) via control of the introduction amount of nitrogen gas, to suppress the amount of reaction gas entering the transfer chamber. The substrate heating base 2 was maintained at 320 degrees.

As shown in FIG. 5, 500 sccm of Ar gas is introduced from the valves 20, 23 in step 1. Before the process was started, the system was exhausted for approx. 30 seconds in this condition. The valve 21 was opened to supply Ru(EtCp)2 gas for a specified time. Normally, material is supplied for approx. 1 second. Next in step 3, the valve 21 was closed, while at the same time the valve 9 was maximally opened to exhaust from the showerhead. When this happens, roughly simultaneously the valve 22 was opened to introduce approx. 2,000 sccm of purge gas. After purge gas was supplied for 1 second through the gas introduction pipe 10 to remove residual Ru(EtCp)2 gas from the gas dispersion part having the gas dispersion nozzle 11 and gas dispersion guide 8, the valve 22 was closed and then the valve 9 was closed. In the next step, the valve 24 was opened to introduce 1,000 sccm of NH3 gas.

Normally, NH3 gas was supplied for 1 second and RF plasma of 13.56 MHz was applied to a RF introduction terminal 33. An optimal power setting in a range of 200 W to 1,000 W was used. RF application was then stopped, and the valve 24 was closed. When this happens, roughly simultaneously the valve 32 was opened to exhaust the interior of the dispersion part 7. Also, roughly simultaneously the Ar gas flow rate from the valve 23 was increased to 2,000 sccm to exhaust the dispersion part 7 more quickly. In the next step, the sequence returned to the initial step where Ru(EtCp)2 gas is introduced, and this cycle was repeated for a specified number of times in accordance with the target film thickness to form film. In the case of Ru film, the film thickness per one cycle is from 0.2 angstrom to 0.3 angstrom.

Next, Ru(EtCp)2 gas was supplied (0.1-100 sccm, preferably 1-10 sccm) from the valve 21 and oxygen was supplied (10-50 sccm) from the valve 24, to implement chemical vapor deposition around Ru film formed via atomic layer deposition through NH3 plasma application and supply of Ru(EtCp)2, thereby growing Ru film further. That is, Ru(EtCp)2 was supplied from the valve 21, and oxygen gas was supplied from the valve 24. As soon as oxygen gas was supplied, nitrogen gas was introduced at an appropriate flow rate from a valve 40 to dilute oxygen gas and thereby controlled the partial pressure of oxygen (the partial pressure of oxygen is 1-5% of the total pressure) to an optimal level. Normally, the nitrogen supply flow rate is 1,200 sccm compared to the oxygen flow rate of 30 sccm. Since Ru(EtCp)2 does not come in contact with oxygen gas in the showerhead, reaction only occurs between the showerhead and substrate, despite the extreme high reactivity of the two gases, and consequently Ru film is deposited by normal chemical vapor deposition. After Ru film had been formed for a specified time, the valves 21, 24 were closed, while the valves 9, 32 were opened, to exhaust the showerhead. At the same time, purge gas was supplied from the valves 23, 22 at flow rates of 1,000 sccm to 2,000 sccm, respectively, to purge reaction gas more quickly. After this step, gas supply to the reactor was stopped and the system was evacuated, upon which the process ended and the transfer step was commenced. According to this process, extremely thin Ru film of approx. 1 to 2 nm was formed via atomic layer deposition, after which 5 to 10 nm of Ru film was formed via the chemical vapor deposition method associated with a higher deposition speed. The deposition speed at 320 degrees was approx. 10 nm/min, while the speed of atomic layer deposition at the same condition was 0.4 nm/min, which means that a deposition speed of approx. 25 times the speed of atomic layer deposition was achieved. Also, while Ru film is formed using oxygen gas in chemical vapor deposition, in atomic layer deposition Ru film can be formed in a reducing ambience of plasma using NH3 gas. Therefore, it is possible to form Ru film without oxidizing the base metal, and then grow Ru film to a specified film thickness quickly using oxygen gas. The atomic layer deposition process and chemical vapor deposition process can also be repeated. For example, chemical vapor deposition may be performed after atomic layer deposition, followed by another atomic layer deposition. The purpose of this is to sandwich the Ru film formed by chemical vapor deposition between the Ru films formed by atomic layer deposition to form the final Ru film having smoother surface, because atomic layer deposition can produce smooth Ru film.

In this example, the gas outlet 12 includes 847 pores each having a diameter of 1 mm, and the plate thickness is 30 mm. The gas outlet 6 includes 847 pores each having a diameter of 0.5 mm, and the thickness is 10 mm. Meanwhile, the conductance of the exhaust valve is exhausted through the exhaust duct with a diameter of 40 mm. If the exhaust valve is not used, Ru(EtCp)2 material gas is purged only from the showerhead and therefore a longer purge time of approx. 10 seconds is required. By using the exhaust valve 9, purge can be implemented at a conductance of approx. four times or greater, and the purge time can be reduced to 1 second or less as a result. Similarly, the parts where NH3 and O2 gases are introduced can be purged over extremely short periods. As for the lower gas dispersion chamber 7 where gases that can be purged relatively easily are introduced, depending on the gas type purge can be implemented only through the gas outlet pores 6 in the shower plate without having to provide the exhaust valve 32.

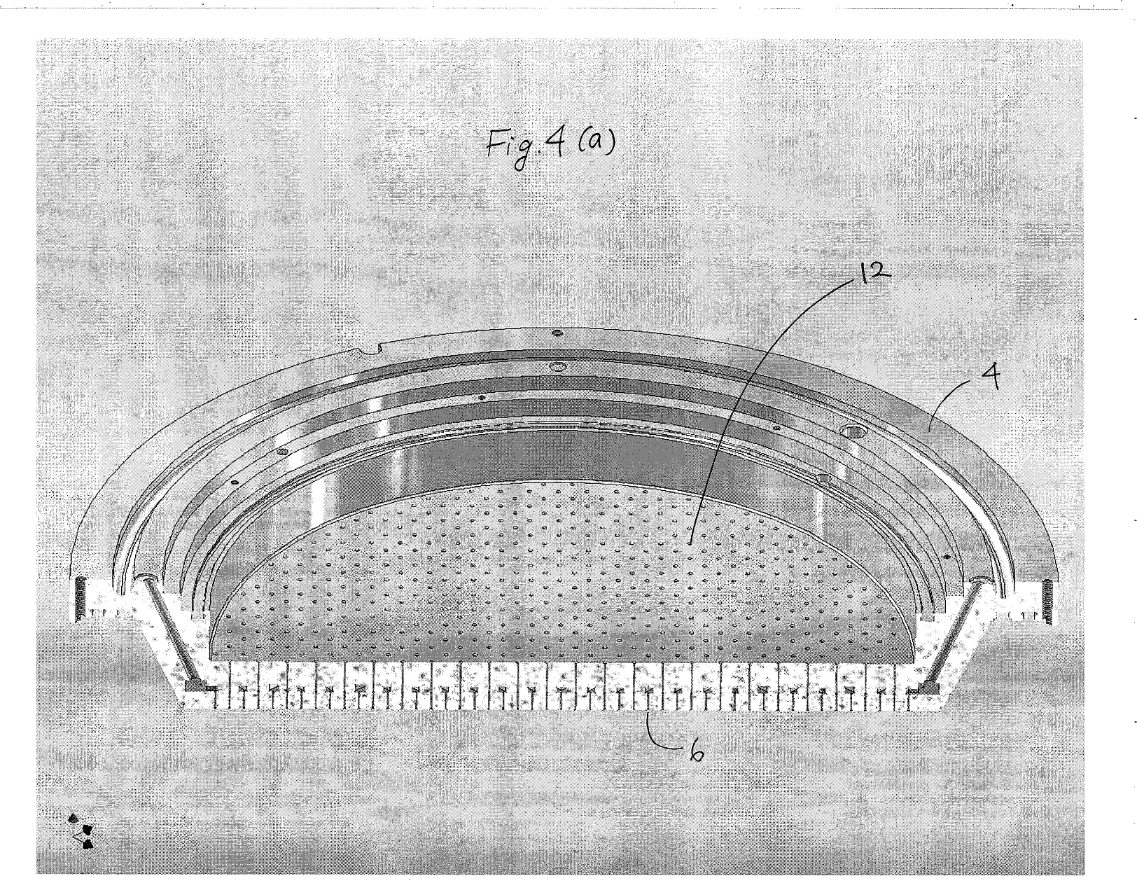

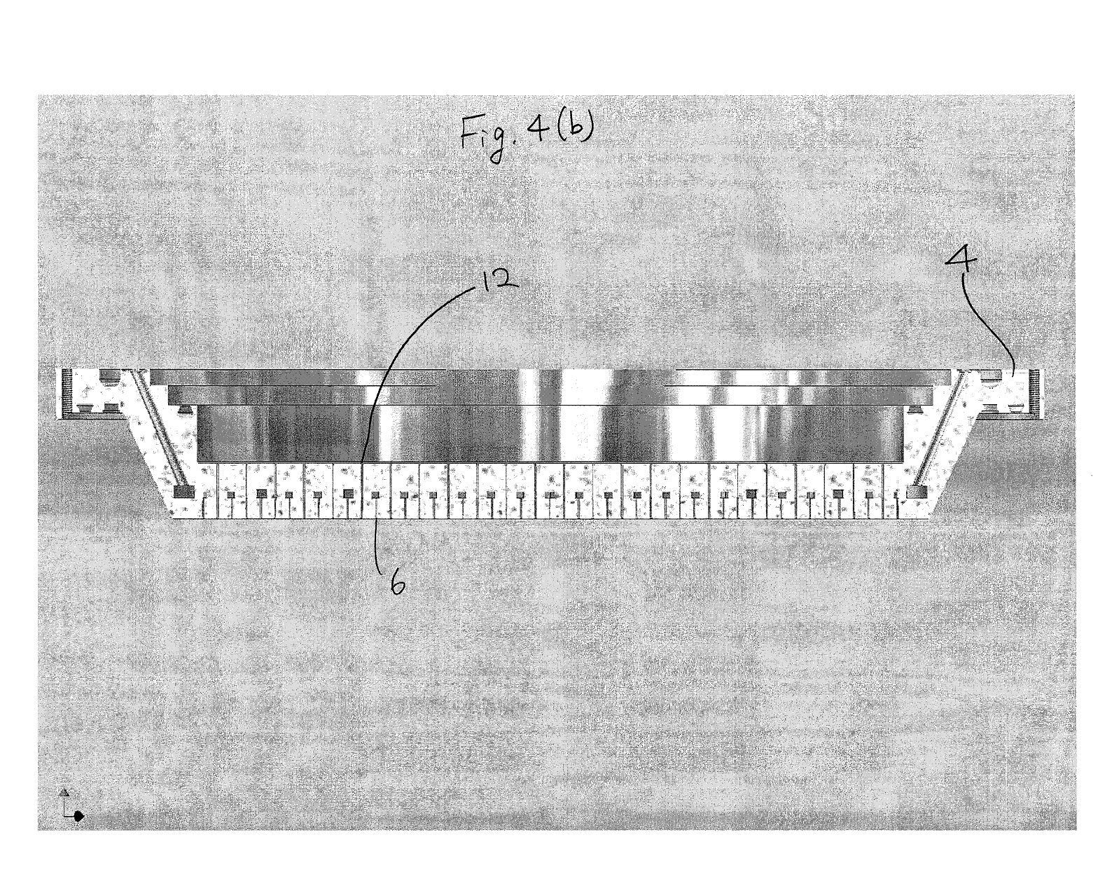

According to the thin-film formation apparatus of the present example, Ru(EtCp)2, NH3 and O2 can be discharged extremely efficiently through the exhaust valve provided at the showerhead, and the post-mix structure also suppresses film deposition inside the showerhead. As a result, Ru film can be formed at extremely high productivity. Similar effects can be achieved even when the material gases are WF6 and NH3, or WF6 and TEB (tetraethyl boron) and NH3, for example. Particularly when WF6, TEB and NH3 are used, TEB and NH3 can be introduced from one showerhead, while the reaction of WF6 and NH3 is suppressed, to implement atomic layer deposition or form WN film or WNC film by means of chemical vapor deposition. FIG. 4(a) and FIG. 4(b) show the post-mix showerhead with a gas outlet of constant surface density, used in the present examples. Ru(EtCp)2 material is supplied from the valve 21, introduced onto the showerhead dispersion plate shown in FIG. 1 (a), and then supplied toward the substrate from the outlet 12. Similarly, NH3 gas or O2 gas is supplied from the valve 24, supplied into the lower dispersion chamber 7, and then supplied onto the substrate surface from the outlet 6. In this shower plate, the gas outlet 12 includes 900 pores with a pitch of 9.3 mm and diameter of 1 mm, and the plate thickness is 30 mm. The gas outlet 6 includes 900 outlets with a pitch of 9.3 mm and diameter of 0.5 mm, and the thickness is 10 mm. Meanwhile, the conductance of the exhaust valve is exhausted through the exhaust duct with a diameter of 40 mm. If the exhaust valve is not used, material gas is purged only through the shower plate and therefore a purge time of approx. four times or longer is required. In FIG. 4(a) and FIG. 4(b), NH3 gas and O2 gas are introduced to the shower plate from the edge of the shower plate. It is also possible to design the apparatus so that gases are introduced from the center of the shower plate.

### EXAMPLE 2

This example explains a process of forming tantalum nitride film using tertiaryamylimidotris(dimethylamido)tantalum (TaN(C4H9)(NC2H6)3), which is an organic metal material of TA, and NH3. The apparatus used in the present example, which is shown in FIG. 1(a), applies RF to the shower plate 4 using the RF feed-through part denoted by 33. In this case, the substrate heating base serves as a ground, and RF is applied onto the shower plate. A silicon substrate is transferred into the reaction chamber 1 from a vacuum transfer chamber (not illustrated), after which the residual water, oxygen, etc., are fully discharged using the turbo pump 7. Next, the substrate is moved to a specified position by means of the up/down mechanism of the substrate heating base 2. At this time, the gap between the dispersion plate 4 and substrate surface is set to a range of 8 to 20 mm. In this example, the process was performed with this gap adjusted to 20 mm.

FIG. 6 shows an example of the sequence of this process. In this example, the process consists of a step to form TaN film and a post-processing step in which TaN film is processed by plasma NH3. The following explains how these steps are repeated to form TaN film of low resistance.

As shown in FIG. 6, 500 sccm of Ar gas was introduced from the valves 20, 23 in step 1. Before the process was started, the system had been exhausted for approx. 30 seconds in this condition. The valves 21, 24 were opened to supply TaMO gas and NH3 gas for a specified time. Since both gases are supplied from the gas outlets 13, 6 onto the substrate surface, they do not come in contact with each other inside the showerhead, which accelerates film deposition on the substrate surface by means of chemical vapor reaction. After the above processing had been performed for a specified time, the valves 21, 24 were closed, while the exhaust valves 9, 32 were opened, and nitrogen purge gas is introduced from the valves 22, 40 to discharge reaction gas. Thereafter, the valves 22, 40 were closed, and then the exhaust valves 9, 32 were closed. Next, NH3 gas was introduced from the valve 24 and RF plasma is applied to produce NH3 plasma to post-process TaN film using plasma. This removes hydrocarbons that remain as impurities in TaN film. Next, RF plasma was stopped, the valve 24 was closed, and the valve 32 was opened, to discharge NH3 gas. At this time, the valve 40 was opened to introduce nitrogen purge gas. Thereafter, the valves 32 and 40 were closed. By repeating the aforementioned TaN film deposition step and the NH3 plasma processing step for a specified number of times, TaN film of low resistance (approximately 1000 μΩcm) was able to be obtained. After completing the process for a specified number of times, all gas valves are stopped and the system is evacuated to proceed to the transfer step. In the process of the present example, TaN film formed by 10 cycles exhibits resistance of 20 to 50% lower than the resistance of TaN film formed by one cycle. The lower resistance is probably due to reduction of impurities in film.

### EXAMPLE 3

### Virtual Example

The present example shows an example of forming a barrier metal by plasma ALD after forming a metal pore sealing layer by either CVD reaction or thermal ALD on SiOC film of low dielectric constant insulation film having pores using the apparatus of FIG. 1(a).

First, Taimata (tertiaryamylimidotrid(dimethylamido)tantalum) and NH3 gas are supplied at the same time from dispersion rooms of separate showerheads. In this embodiment, there are cases where a supplying method is to supply each of the materials simultaneously and continuously for a predetermined time and where a supplying method is to repeat a predetermined supplying time and a predetermined exhaust time upon stopping supplying. Process time of the latter case is shown in Table. 3 below.

TABLE 3

Process

| | Process 1 | Process 2 |
|---|---|---|
| Upper dispersion chamber | Taimata | Purge with Ar |
| Lower dispersion chamber | NH3 | Purge with Ar |
| Time | 5 sec | 3 sec |

In the above, Taimata is supplied into an upper gas introducing pipe 10 (process 1). NH3 gas is supplied into a lower gas dispersion chamber 7. After each of the gases is run for 5 seconds, each dispersion chamber is vacuum evacuated while purging with argon (process 2). A first TaNC film by thermal ALD is formed by repeating this cycle once or more (twice, or more than twice).

Next, a second TaNC film is formed on the first TaNC film according to the process conditions in Table. 4. Specifically, Taimata is supplied into the first dispersion chamber of the showerhead (process 1), Ar gas is introduced for purging (process 2), hydrogen plasma is generated by introducing hydrogen into at least either the first dispersion chamber or the second dispersion chamber (process 3), purging is performed with Ar gas (process 4), and this cycle is repeated predetermined number of times (times necessary to form a required film thickness. A hundred times, for example, in the case of growing 0.3 angstrom thickness per one cycle and requiring 30 angstrom of a final thickness), thereby the second film is formed by plasma ALD. Normally, the cycle is repeated 30-150 times when a final thickness is set 1-4 nm.

TABLE 4

| | Process | | | |
|---|---|---|---|---|
| | Process 1 | Process 2 | Process 3 | Process 4 |
| Upper | Taimata | Purge with Ar | Ar or H2 | Purge with Ar |
| dispersion | | | plasma | |
| chamber | | | | |
| Lower | Ar | Purge with Ar | H2 (plasma) or | Purge with Ar |
| dispersion | | | Ar | |
| chamber | | | | |
| Time | 1 sec | 1 sec | 3 sec | 1 sec |

The first TaNC film (Table. 3) by thermal ALD does not diffuse into a pore having approximately 1 μm in a low dielectric constant film, thereby TaNC film is readily formed. Since plasma is not used for the first TaNC film, a TaNC film can be formed on a surface without having a low dielectric constant insulation film damaged, and also good bonding property is achieved. However, resistivity is relatively high, which is 1000-3000 μΩcm. In the meantime, in the case of the second TaNC film using plasma as per FIG. 4, although a TaNC film can be formed having a low dielectric constant without diffusing into a pore, there is a possibility that a surface of the low dielectric film gets damaged if the second TaNC film is formed directly on the surface of the low dielectric film. Thus, in the present example, the first TaNC film is formed on the low dielectric film by thermal ALC without using plasma, then the second TaNC film is formed by plasma ALD, thereby a TaNC film having resistivity approximately 200-1000 μΩcm (preferably approximately 300-400 μΩcm) can be formed without having the surface of the low dielectric film damaged. This successive process enables to readily form the wiring process for high-speed logic of the next generation.

Further, by using the method of the present example, a barrier metal can be implemented on the low dielectric constant insulation film having a pore size of approximately 1 μm with good bonding property in the same chamber successively.

In addition, Table. 4 is an embodiment wherein a dispersion chamber uses a showerhead separated into upper and lower. A metal material runs in the upper dispersion chamber (the first dispersion chamber) and is absorbed inside thereof. Since a film is formed inside thereof when hydrogen passes through, it is preferred that film forming inside the dispersion chamber is prevented by running hydrogen in the lower dispersion chamber (the second dispersion chamber). In the case where the metal material does not react with hydrogen in contact, a treatment can be performed in a single dispersion chamber.

As explained above, according to an embodiment of the present invention, a post-mix showerhead capable of supplying two types of gases onto the substrate surface is used, and an exhaust valve is installed for each dispersion chamber in the showerhead, to achieve an atomic layer deposition process requiring a short purge time. At the same time, supply of two reaction gases from the post-mix showerhead enables chemical vapor deposition. According to another embodiment, by installing a dedicated exhaust port with a high-speed open/close valve or variable-conductance valve for each gas dispersion chamber, residual gas can be fully purged at a high speed of 1,000 msec to 100 msec. Therefore, the thin-film formation process proposed by an embodiment of the present invention allows for very easy replacement of reaction gas in the showerhead, which provides a practical process unlike the conventional processes that are not considered practical because the atomic layer deposition process and chemical vapor reaction need to be repeated or chemical vapor deposition and plasma heat treatment need to be repeated 10 to 100 times. Furthermore as a secondary benefit, an embodiment of the present invention can reduce particles during atomic layer deposition. Also, in a reaction where chemical activity is achieved only when high-frequency waves are applied to one gas, reaction is stopped when plasma is stopped and therefore purge is no longer necessary. In this case, thin film can be formed with superior efficiency by providing a dedicated exhaust port and exhaust valve only for the dispersion chamber into which the applicable metal material gas is introduced. While it is desirable to provide one exhaust valve for each dispersion chamber in the showerhead, provision of an exhaust valve for each dispersion chamber is not always necessary if material gas is not metal gas, in which case quick purge can be achieved by reducing the dispersion chamber volume and increasing the purge flow rate without providing an exhaust valve for each dispersion chamber. Needless to say, however, reaction gas can be exhausted with the maximum efficiency by providing a dedicated exhaust valve for every dispersion chamber.

The present invention includes the above mentioned embodiments and other various embodiments including the following:

1) A method for forming a thin film using a thin-film formation apparatus, comprising a gas supply apparatus configured to be connected to an evacuatable reaction chamber provided with a support for placing a substrate thereon, and a gas dispersion head to introduce gas into the chamber through a head surface, comprising a first section to discharge gas through the head surface in the direction of a support, and a second section to discharge gas through the head surface in the direction of the support, wherein the first and second sections are separately superposed from each other in the gas dispersion head so as not to have a gas passage, and wherein the first section is connected to an exhaust system for purging therefrom a gas present in the corresponding section without passing through the head surface: a thin-film formation method characterized by comprising as the process for forming thin film: a step to discharge reaction gas A from the first section; a step to stop reaction gas A and open an open/close valve connected to the first section and exhaust side; a step to introduce purge gas into the first section; a step to discharge reaction gas B from the second section; a step to stop reaction gas B and introduce purge gas into the second section, where the aforementioned steps are repeated to form a first thin film on the substrate (atomic layer deposition process); and a step to discharge reaction gas C from the first section and reaction gas D from the second section to implement chemical vapor deposition on the substrate surface to form a second thin film on the first thin film (chemical vapor deposition process).

2) A method for forming a thin film using a thin-film formation apparatus, comprising a gas supply apparatus configured to be connected to an evacuatable reaction chamber provided with a support for placing a substrate thereon, and a gas dispersion head to introduce gas into the chamber through a head surface, comprising a first section to discharge gas through the head surface in the direction of a support, and a second section to discharge gas through the head surface in the direction of the support, wherein the first and second sections are separately superposed from each other in the gas dispersion head so as not to have a gas passage, and wherein the first and second sections are connected to an exhaust system for purging therefrom a gas present in the corresponding section without passing through the head surface: a thin-film formation method characterized by comprising as the process for forming thin film: a step to discharge reaction gas A from the first section; a step to stop reaction gas A and open an open/close valve connected to the first section and exhaust side; a step to introduce purge gas into the first section; a step to discharge reaction gas B from the second section; a step to stop reaction gas B and open an open/close valve connected to the second section and exhaust side; a step to introduce purge gas into the second section, where the aforementioned steps are repeated to form a first thin film on the substrate (atomic layer deposition process); and a step to discharge reaction gas C from the first section and reaction gas D from the second section to implement chemical vapor deposition on the substrate surface to form a second thin film on the first thin film (chemical vapor deposition process).

3) The method for forming the thin film according to the above-mentioned

1) or 2), characterized in that the chemical vapor deposition process is performed, then the atomic layer deposition process is performed.

4) The method for forming the thin film according to the above-mentioned 1) or 2), characterized in that the atomic layer deposition process is performed, then the chemical vapor deposition process is performed.

5) The method for forming the thin film according to the above-mentioned 1), 2), 3), or 4), characterized in that the reaction gas A and the reaction gas C are the same.

6) The method for forming the thin film according to the above-mentioned 1), 2), 3), 4), or 5), characterized in that the reaction gas B and the reaction gas D are the same.

7) The method for forming the thin film according to the above-mentioned 1), 2), 3), 4), 5), or 6), characterized by comprising a step for treating the formed thin film after at least either the chemical vapor deposition process or the atomic layer deposition process, and repeating these processes at least once.

8) The method for forming the thin film according to the above-mentioned 7), characterized in that the step for treating the formed thin film is any one of a heat treatment, a plasma treatment applying high frequency, a irradiation treatment with light, and a treatment with an activated gas.

9) The method for forming the thin film according to any one of the above-mentioned 1) through 8), characterized in that a gas outlet of the showerhead from each section is arranged at constant surface density over an area at least larger than the substrate.

10) The method for forming the thin film According to any one of the above-mentioned 1) through 9), characterized in that the reaction gas introduced into the first section is introduced from a center of the first section.

11) The method for forming the thin film according to any one of the above-mentioned 1) through 9), characterized in that the reaction gas introduced into the second section is introduced from a peripheral part of the second section.

12) The method for forming the thin film, characterized by using a thin-film formation apparatus, comprising a gas supply apparatus configured to be connected to an evacuatable reaction chamber provided with a support for placing a substrate thereon, and a gas dispersion head to introduce gas into the chamber through a head surface, comprising a first section to discharge gas through the head surface in the direction of a support, and a second section to discharge gas through the head surface in the direction of the support, wherein the first and second sections are separately superposed from each other in the gas dispersion head so as not to have a gas passage, and wherein the first section is connected to an exhaust system for purging therefrom a gas present in the corresponding section without passing through the head surface, a thin-film formation method characterized by including as the process for forming thin film: a step to discharge reaction gas A from the first section and reaction gas B from the second section for a specified time and implement chemical vapor deposition on the substrate surface to form a first thin film; a step to open an exhaust valve connected to the first section to discharge the reaction gas A, discharge reaction gas B from the second section, and then introduce purge gas into each of the sections; and a step to discharge reaction gas C from at least either the first section or second section for a specified time, after which reaction gas C is stopped and discharged, and then purge gas is introduced into the sections.

13) The method for forming the thin film, characterized by using a thin-film formation apparatus, comprising a gas supply apparatus configured to be connected to an evacuatable reaction chamber provided with a support for placing a substrate thereon, and a gas dispersion head to introduce gas into the chamber through a head surface, comprising a first section to discharge gas through the head surface in the direction of a support, and a second section to discharge gas through the head surface in the direction of the support, wherein the first and second sections are separately superposed from each other in the gas dispersion head so as not to have a gas passage, and wherein the first section is connected to an exhaust system for purging therefrom a gas present in the corresponding section without passing through the head surface: a thin-film formation method characterized by including as the process for forming thin film: a step to discharge reaction gas A from the first section and reaction gas B from the second section for a specified time and implement chemical vapor deposition on the substrate surface to form a first thin film; a step to open an exhaust valve connected to the first section and an exhaust valve connected to the second section to discharge the reaction gases A, B and then introduce purge gas into each of the sections; and a step to discharge reaction gas C from at least either the first section or second section for a specified time, after which reaction gas C is stopped and discharged, the exhaust valve connected to either the first or second section is opened to discharge reaction gas C, and then purge gas is introduced into the sections.

14) The method for forming the thin film according to the above-mentioned

12) or 13), characterized in that high-frequency plasma is generated within a predetermined time to discharge the reaction gas C.

15) The method for forming the thin film according to the above-mentioned 12) or 13), characterized in that the reaction gas C and the reaction gas B are the same gas.

16) The method for forming the thin film according to any one of the above-mentioned 12), 13), 14), and 15), characterized in that the step for forming the first thin film and the step for discharging the reaction gas C are repeated multiple times.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A method for forming a thin film on a substrate using a showerhead comprising an upper compartment and a lower compartment which is disposed underneath and overlapped by the upper compartment as viewed in an axial direction of the showerhead and is not gas-communicated with the upper compartment, wherein a surface of the showerhead facing a susceptor has an overlapping region in which the upper compartment and the lower compartment are overlapped as viewed in the axial direction of the showerhead, and in the overlapping region, the showerhead has first bores being gas-communicated with the upper compartment without being gas-communicated with the lower compartment, and second bores being gas-communicated with the lower compartment without being gas-communicated with the upper compartment, said method comprising the steps of:
(i) discharging a first gas from the upper compartment through the first bores of the showerhead into a reaction space toward a substrate on the susceptor;
(ii) after step (i), discharging a second gas from the lower compartment through the second bores of the showerhead into the reaction space toward the substrate;
(iii) repeating preceding steps including steps (i) and (ii) to form a first film on the substrate; and
(iv) discharging a third gas and a fourth gas from the upper compartment through the first bores and the lower compartment through the second bores, respectively, to form a second film on the first film which is different from the first film.

2. The method according to claim 1, further comprising step (ia) of purging the upper compartment with a purge gas between steps (i) and (ii).

3. The method according to claim 2, wherein the upper compartment is provided with an exhaust port for evacuating predominantly the upper compartment, said method further comprising step (ib) of evacuating the upper compartment through the exhaust port between steps (ia) and (ii).

4. The method according to claim 1, further comprising step (iia) of purging the lower compartment with a purge gas between steps (ii) and (iii).

5. The method according to claim 4, wherein the lower compartment is provided with an exhaust port for evacuating predominantly the lower compartment, said method further comprising step (iib) of evacuating the lower compartment through the exhaust port between steps (iia) and (iii).

6. The method according to claim 1, wherein step (iv) further comprises applying RF power to the reaction space.

7. The method according to claim 1, wherein the first film is constituted by an atomic layer deposition film.

8. The method according to claim 1, wherein the second film is constituted by a chemical vapor deposition film.

9. The method according to claim 1, wherein the first gas and the third gas are the same gas.

10. The method according to claim 1, wherein the second gas and the fourth gas are the same gas.

11. The method according to claim 1, wherein the upper compartment has a gas inlet port positioned in its center through which the first gas and the third gas are supplied to the upper compartment.

12. The method according to claim 1, wherein the lower compartment has a gas inlet port positioned at its periphery through which the second gas and the fourth gas are supplied to the lower compartment.

13. The method according to claim 1, further comprising step (iic) of applying RF power to the second gas between steps (i) and (ii).

14. The method according to claim 1, wherein step (iv) comprises:
(iva) discharging the third gas from the upper compartment through the first bores of the showerhead into the reaction space toward the substrate;
(ivb) after step (iva), discharging the fourth gas from the lower compartment through the second bores of the showerhead into the reaction space toward the substrate;
(ivc) applying RF power to the fourth gas; and
(ivd) repeating preceding steps in step (iv) including steps (iva) through (ivc) to form the second film on the first film.

15. The method according to claim 1, wherein step (iv) comprises:
(iva) discharging the third gas from the upper compartment through the first bores of the showerhead into the reaction space toward the substrate;
(ivb) purging the upper compartment with a purge gas;
(ivc) discharging a fifth gas from the upper compartment through the first bores of the showerhead into the reaction space toward the substrate;
(ivd) applying RF power to the fifth gas; and
(ive) repeating preceding steps in step (iv) including steps (iva) through (ivd) to form the second film on the first film.

16. The method according to claim 1, wherein the substrate has an insulation layer on which the first film is formed.

17. The method according to claim 1, wherein the first film containing ruthenium.

18. The method according to claim 1, wherein the second film containing ruthenium.

19. A method for forming a thin film on a substrate using a showerhead comprising an upper compartment and a lower compartment which is disposed underneath and overlapped by the upper compartment as viewed in an axial direction of the showerhead and is not gas-communicated with the upper compartment, wherein a surface of the showerhead facing a susceptor has an overlapping region in which the upper compartment and the lower compartment are overlapped as viewed in the axial direction of the showerhead, and in the overlapping region, the showerhead has first bores being gas-communicated with the upper compartment without being gas-communicated with the lower compartment, and second bores being gas-communicated with the lower compartment without being gas-communicated with the upper compartment, said method comprising the steps of:
(i) discharging a first gas from the upper compartment through the first bores of the showerhead into a reaction space toward a substrate on the susceptor;
(ii) discharging a second gas from the lower compartment through the second bores of the showerhead into the reaction space toward the substrate;
(iii) optionally applying RF power to the reaction space, thereby forming a first film on the substrate; and
(iv) discharging a third gas from at least one of the upper compartment through the first bores and the lower compartment through the second bores into the reaction space to treat a surface of the first film on the substrate.

20. The method according to claim 19, further comprising step (ia) of purging the upper compartment with a purge gas between steps (i) and (iv).

21. The method according to claim 20, wherein the upper compartment is provided with an exhaust port for evacuating predominantly the upper compartment, said method further comprising step (ib) of evacuating the upper compartment through the exhaust port between steps (ia) and (iv).

22. The method according to claim 19, further comprising step (iia) of purging the lower compartment with a purge gas between steps (ii) and (iv).

23. The method according to claim 22, wherein the lower compartment is provided with an exhaust port for evacuating predominantly the lower compartment, said method further comprising step (iib) of evacuating the lower compartment through the exhaust port between steps (iia) and (iv).

24. The method according to claim 19, wherein step (iv) further comprises exciting the third gas to treat the surface of the first film of the substrate.

25. The method according to claim 24, wherein the excitation of the third gas is performed by heat or plasma.

26. The method according to claim 19, wherein steps (i) through (iv) are repeated.

27. The method according to claim 19, wherein step (iv) comprises:
(iva) discharging the third gas from the upper compartment through the first bores of the showerhead into the reaction space toward the substrate;
(ivb) after step (iva), discharging a fourth gas from the lower compartment through the second bores of the showerhead into the reaction space toward the substrate;
(ivc) repeating preceding steps including steps (iva) and (ivb) to form a second film on the first film on the substrate as the treatment of the first film.
